(19) United States
(12) Patent Application Publication
(10) Pub. No.: US 2006/0018100 A1
(43) Pub. Date: Jan. 26, 2006

(54) Active plate-connector device with built-in semiconductor dies

(76) Inventor: Yunxing Guo, Westland, MI (US)

Correspondence Address: Yunxing Guo, Apt R-06, 37775 Greenwood St, Westland, MI, 48185, US

(21) Appl. No.: 10/895,302

(22) Filed: Jul. 21, 2004

(51) Int. Cl. H05K 7/20; H02K 7/10; H02P 1/00

(52) U.S. Cl. 361/719

(57) ABSTRACT

An Active Plate-Connector Device has built-in semiconductor dies to switch large current. The signal pads of the dies are routed out through a built-in printed circuit board and associated pins. The power pads of the dies are connected to the power plate and power terminals, respectively. The power plate, power terminals, mating terminals and wires connected to the mating terminals all serve as heat sinks for the large-current-handling device. Built-in temperature sensors monitor die temperature for every channel. The ON resistance of the new device is virtually the die resistance. The unique package adds little resistance to the overall device resistance. The current capacity of the new device is more than three times higher compared to the traditional package with the same die.

### BACKGROUND OF THE INVENTION

In automobile industry, battery power is distributed through a module called Power Distribution Center (PDC), or Power Management Module. PDC works like a power panel. It distributes power from battery and alternator to various loads such as lights, pumps, blowers, radiator fan, door locks, power windows as well as other control modules, such as Engine Control Module, Antilock Brake Module, Air-Bag Module, etc. In addition to controlling power distribution, PDC provides various protections such as short circuit protection, overload protection, overheat protection, etc.

Historically, PDC utilizes relays and fuses to switch loads ON/OFF and perform short circuit protection. There are a lot of disadvantages associated with relays. Large size, contact arc, ware and tare are problems. Large coil power consumption is another problem.

With the development of semiconductor technology such as MOSFET, IGBT, etc., more and more relays are replaced by semiconductor switches. For the same current-handling capacity, the ON resistance of a semiconductor transistor is the same or even lower than the relay contact-resistance while the size is only a fraction of the relay. Unlike relays, when a semiconductor switch is turned ON, it needs little current to hold it ON. Semiconductor device works very well for low level current. However, when the load current is large, such as 10 A, 20 A, 50 A or more, there is a packaging problem of the semiconductor itself. There is a PCB trace problem. There is also a heat dissipation problem on the PCB.

For a semiconductor device, packaging is the bottleneck to reduce the ON resistance and current carrying capacity. For example, a semiconductor die has 1.0 mΩ ON resistance, but the packaged device resistance increases to 2.4 mΩ. The die can carry 307 A current, but the packaged device can carry only 100 A due to the limited space for pins and bonding wires in the package.

For large current, the copper on a PCB must be thick. Copper trace must be wide. It is expensive and difficult to make copper thicker than 10 OZ on the PCB. Even 10 OZ copper is not thick enough for large current. Wide trace not only takes large board space, but also is difficult to route to the board connectors for load connection. Wide traces must be narrowed down when they approach to the connectors. As a result, the copper trace consumes significant amount of energy. The copper loss could be up to 30% of the semiconductor loss. Both the copper loss and semiconductor loss are turned into heat. There was an experience that a 100 A PDC was burned out due to accumulative heat generated by PCB trace and semiconductor. To prevent fire hazard, PDC must be large and ventilated. Small size and good thermal property is not possible with packaged semiconductor devices on the PCB.

### SUMMARY OF THE INVENTION

The present invention moves all large-current semiconductors out of main PCB. The semiconductor dies are used in their die form. The semiconductor dies are installed inside a plate-connector device. The plate-connector device includes power plate, power terminals, built-in PC board, dies, sensors, signal pins, etc. The power plate is the common power input for all channels. It is made of thick metal. The substrates of all semiconductor dies are soldered on the power plate. The power supply is directly connected to the power plate. The power terminals are the output of the device. Each channel has at least one power terminal. One section of the power terminals are connected to the output of the semiconductor dies through bonding wires or soldering means. The other section of the power terminals is connected to various loads through mating terminals and wires. The built-in PC board holds signal pins, sensors, etc. and provides signal pads for control and sense signal connection to semiconductor dies. The signal pads on built-in PC board are connected to signal pads of a die, such as gate pads, current-sense pads, temperature-sense pads, etc. with wire-bonding method or soldering method.

Since the dies are directly mounted on the power plate, the plate serves as a good heat sink. In addition, the unique structure thermally connects the power terminals to the dies. As a result, the power terminals, the mating terminals and the wires connected to the mating terminals also serve as heat sinks.

If a PDC has many high-current channels, several connectors can share the same power plate to form a single plate—multi connector device. The connection between a main PCB and the plate-connector device has only signal pins. There is no large current device on the main PCB. There is no large current flowing between the main PCB and the plate-connector device. The main PCB performs control functions such as ON/OFF, short circuit protection, overload protection, thermal protection, over voltage protection, under voltage protection, etc. through these signal pins. The ON resistance of the plate-connector device is virtually the die resistance. The unique package adds little resistance to the overall resistance. As a result, the maximum device current is the maximum die current, not limited by the package. The current capacity of the new device is more than three times higher compared to the traditional package. Since there is no large current trace on the main PCB, the traces on the PCB can be very narrow. The components can be densely populated on the board and the board size will be very small. With invented structure, the traditional packaging problem, thermal problem and PCB copper trace problem are all solved by the following methods: moving power devices out of main PCB, allowing spacious space for packaging compared to old package, connecting dies directly to a big power plate, connecting dies directly to a big power terminal, Reducing heat source by reducing the package resistance.

### BRIEF DESCRIPTION OF THE DRAWING

FIG. 1 is the drawing for wire bonding connection with a separate PC Board illustration.

FIG. 2 is the drawing for soldering connection with a separate PC Board illustration.

### DETAILED DESCRIPTION OF THE PREFERRED EMBODIMENTS

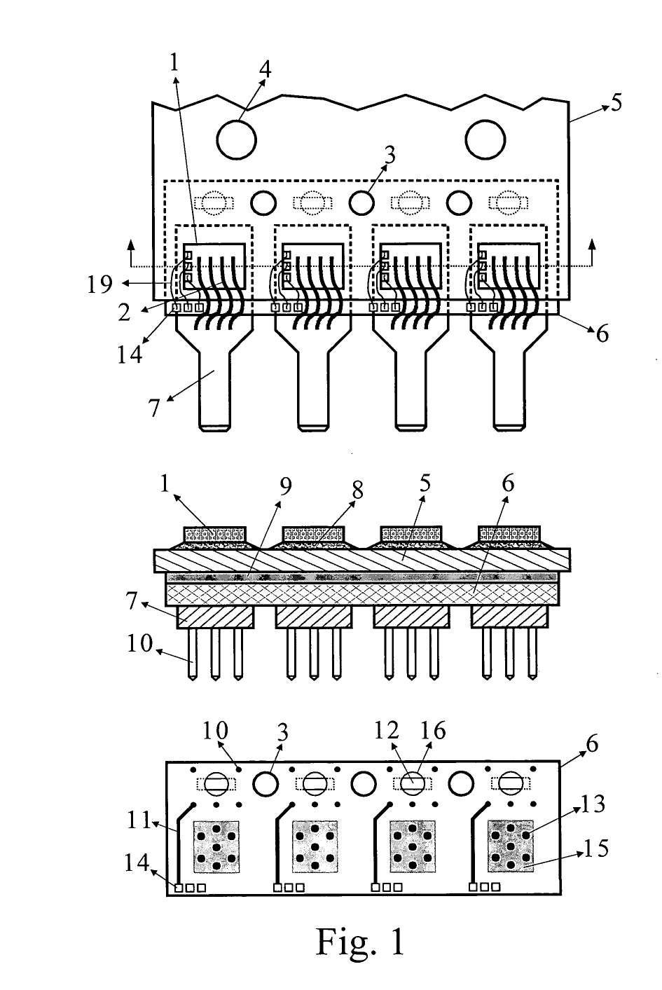

FIG. 1 shows a plate-connector with four power terminals 7. There can be more than one connector sharing the same power plate 5. Each connector can have any number of power terminals 7. The connectors can be at one side of the power plate 5 or at different sides of Power Plate 5. The following description utilizes an N-channel MOSFET die as an example, but the basic structure applies to any other types of semiconductor dies such as P-channel MOSFET, BJT, IGBT, GTO, MCT, etc. even though the pad names are different. In the drawings, if a group of elements have the same shape and size, they are identical elements. For clarity, not all identical elements have legends.

Power plate 5 is made of good conductive metal. Power plate 5 can be connected to power source such as a battery by various means. For example, it can be bolted to the power source through Mounting Holes 4, or welded, or soldered to the power source. The drains of Dies 1 are soldered on Power Plate 5 through solder 8. The sources of Dies 1 are wire-bonded to Power Terminals 7. PC Board 6 and Insulator 9 are sandwiched between Power Plate 5 and Power Terminals 7. Insulator 9 can be a standalone insulation layer or a coated insulation layer on the PC Board 6. Signal pads of Dies 1, such as gate pads, temperature sensor pads, current sensor pads, etc. are wire-bonded to Signal Pads 14 on PC Board 6. Signal Pins 10 are mounted or soldered on the bottom side of PC BOARD 6. Signal Pins 10 are connected to signal pads of Dies 1 through Copper Traces 11 of PC BOARD 6, Signal Pads 14 on PC BOARD 6 and Bonding Wires 19 between PC BOARD 6 and Dies 1. For simplicity, only a few copper traces 11, a few copper pads, a few bonding wires, a few signal pads on the dies and a few signal pins are shown in the drawings. The actual number of those pads, traces, bonding wires and signal pins may be different from those shown in the drawings.

There are copper Thermal Pads 15 on both sides of PC Board 6. Thermal Vies 13 connect Thermal Pads 15 from one side to the other. Power terminals 7 are soldered on the bottom side of PC board 6. Sensors 12 are soldered on the bottom side of PC Board 6 or inside Sensor Holes 16 in PC Board 6. Sensor Holes 16 pass through in Insulator 9. Sensor Holes 16 are filled with thermal conductive material such as thermal grease or thermal compound. Insulator 9 is made of good thermal conductive material. Insulator 9 prevents copper traces on PC Board 6 from being shorted to Power Plate 5. When assembled, PC Board 6 and associated Insulator 9 are attached to Power Plate 7. Sensors 12 are thermally connected to Power Plate 5 through filled thermal conductive material inside Sensor Holes 16. Power Terminals 7 are thermally connected to Power Plate 5 through Thermal Vies 13 and Insulator 9 because Insulator 9 is a thermal conductive material.

One of Signal Pins 10 in each channel is connected to the channel's Power Terminals 7 which is wire-bonded to associated source pad of Dies 1. The source signal of Dies 1 is needed outside the assembly for control purpose. Some Signal Pins 10 are connected to Sensors 12 either directly or through copper traces 11 on PC Board 6, depending on the position of Signal Pins 10.

Signal pads on Dies 1 are wire-bonded to Signal Pads 14 on PC Board 6 by Bonding Wires 19. Source pads on Dies 1 are wire-boned to Power Terminal 7 by Bonding Wires 2. Before wire bonding, it is necessary to hold all pads to be wire-bonded in fixed position. Power Terminals 7 are soldered onto PC Board 6. PC Board 6, Insulator 9 and Power Plate 5 can be held together for wire bonding in any sticky means. The similar process used to glue big surface-mount IC chips to a printed circuit board before reflow is one example.

The plate-connector device is molded in a plastic housing in any connector shapes. The molding structure is not shown in the drawings. Molding Holes 3 pierce through Power Plate 5, insulator 9 and PC Board 6. During molding, plastic is filled inside the holes and forms plastic nails between the top part and the bottom part of the housing to enhance mechanical strength.

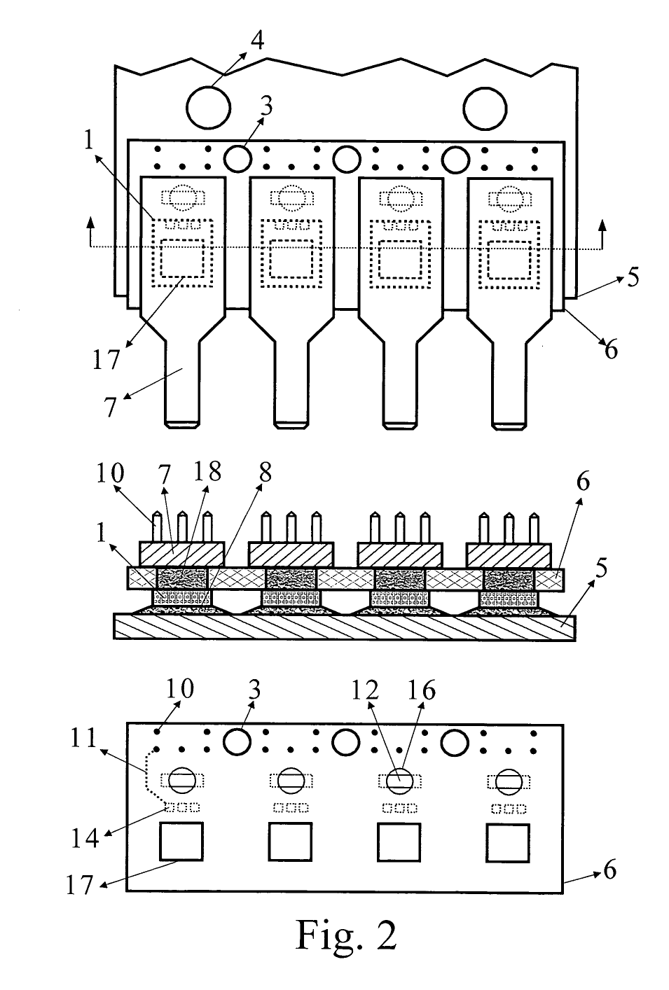

In FIG. 2, Power plate 5 can be connected to power source such as a battery by various means. For example, it can be bolted to the power source through Mounting Holes 4, or welded, or soldered to the power source. The drains of Dies 1 are soldered on Power Plate 5 through solder 8. The sources of Dies 1 are soldered on Power Terminals 7 through solder 18. Solder 18 passes through Solder Holes 17 in PC Board 6. In the drawings, there is one square Solder Hole 17 for each Power Terminal 7. It by no means limits the shape or number of Solder Holes 17. Solder Holes 17 can be any shape and number for each Power Terminal 7. PC Board 6 is positioned between Dies 1 and Power Terminals 7. Signal pads of Dies 1 are soldered onto Signal Pads 14 at the bottom side of PC Board 6. Signal Pads 14 are connected to Signal Pins 10 through Copper Traces 11 of PC Board 6. Sensors 12 are soldered on the bottom side of PC Board 6 or inside Sensor Holes 16 in PC Board 6 and connected to Signal Pins 10. Sensors 12 are thermally connected to Power Terminals 7 through filled thermal conductive material inside Sensor Holes 16.

The plate-connector device is molded in a plastic housing in any connector shapes. The molding structure is not shown in the drawings. Molding Holes 3 pierce through Power Plate 5 and PC Board 6. During molding, plastic is filled inside the holes and forms plastic nails between the top part and the bottom part of the housing to enhance mechanical strength.

What is claimed is:

1. A device for distributing power comprising:
at least one power plate;
at least one power terminal;
at least one joint section and
at least one semiconductor die coupled to said power plate.

2. The device of claim 1 wherein said joint section is made of bonding materials, or printed circuit board, or both.

3. The device of claim 1 wherein said joint section is between said power terminal and said power plate.

4. The device of claim 1 wherein said joint section is between said power terminal and said semiconductor die.

5. The device of claim 1 wherein said power plate and said power terminal are firmly bonded together mechanically but insulated each other electrically.

6. The device of claim 2 wherein said printed circuit board includes at least one of the following: signal pads, signal pins, copper traces, sensors, sensor holes, solder holes, molding holes, thermal vies, thermal pads, stress relief slots and electronic components.

7. The device of claim 6 wherein said signal pads on said printed circuit board are wire-bound to the signal pads on said semiconductor dies.

8. The device of claim 6 wherein said signal pads on said printed circuit board are soldered to the signal pads on said semiconductor dies.

9. The device of claim 1 wherein said power terminals are made of conductive material and wire-bound to the power pads on said semiconductor dies.

10. The device of claim 1 wherein said power terminals are made of conductive material and soldered to the power pads on said semiconductor dies.

11. The device of claim 6 wherein said sensors are thermally coupled to said semiconductor dies.

12. The device of claim 6 wherein said sensor holes are filled with thermally conductive materials.

13. The device of claim 6 wherein said stress relief slots are used to reduce thermal stress.

14. The device of claim 1 wherein said power plate is made of conductive material, coupled to a power source and used as heat sink for said semiconductor dies.

15. The device of claim 1 wherein said power terminals are coupled to loads and are used as heat sink for said semiconductor dies.

16. A method of using bonding materials to bond said power terminals and power plate firmly together through said joint section to form an assembly or to bond power terminals and dies firmly together through said joint section to form an assembly.

17. The device of claim 16 wherein said bonding materials penetrate said assembly through holes in said assembly to enhance mechanical strength for said assembly.

18. The device of claim 16 wherein said assembly is stand alone or is part of an enclosure.

19. A method of dissipating heat from one side of said semiconductor die to said power plate and from the other side of said semiconductor die to said power terminal.
